(19) United States
(12) Patent Application Publication
(10) Pub. No.: US 2010/0148080 A1
(43) Pub. Date: Jun. 17, 2010

(54) IMAGING APPARATUS AND RADIATION IMAGING SYSTEM

(75) Inventors: Tadao Endo, Honjo-shi (JP); Toshio Kameshima, Kumagaya-shi (JP); Tomoyuki Yagi, Honjo-shi (JP); Katsuro Takenaka, Honjo-shi (JP); Keigo Yokoyama, Honjo-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/516,615

(22) PCT Filed: Sep. 3, 2008
(86) PCT No.: PCT/JP2008/066269

§ 371 Date: May 28, 2009

(30) Foreign Application Priority Data
Sep. 7, 2007 (JP) 2007-233313

(51) Int. Cl. G01T 1/24; G01T 1/17

(52) U.S. Cl. 250/370.08; 250/394; 250/393

(57) ABSTRACT

First drive wirings electrically connected to output switching elements TT11 to TT63 in a plurality of n-th row pixels 111 and second drive wirings electrically connected to initializing switch elements TR11 to TR63 in a plurality of pixels 111 along a predetermined row are connected to a first drive circuit unit 121 arranged on a first side of a glass substrate 10. Third drive wirings electrically connected to output switching elements in a plurality of n+1-th row pixels 111 and fourth drive wirings electrically connected to initializing switch element in a plurality of pixels 111 along another row different from a predetermined row are connected to a second drive circuit unit 122 arranged along a second side in opposition to the first side of the glass substrate 10 sandwiching the converting unit 110 between the first and second sides. Thereby, the drive circuit unit can be electrically and simply implemented and freedom of selection of an output operation mode can be secured so that a high quality image subjected to reduction of shading influence can be realized and obtained.

### TECHNICAL FIELD

The present invention relates to an imaging apparatus and a radiation imaging system preferably used for medical diagnosis and industrial nondestructive inspection. Radiation in the specification hereof will include X-ray, α-ray, β-ray and γ-ray.

### BACKGROUND ART

In the recent years, demands for digitalizing X-ray images are increasing within a hospital setting. Film is already being replaced by X-ray imaging apparatus with a planar detector including conversion elements arranged in a two dimensional matrix. Such conversion elements convert X-ray into electric signals. Such a planar detector will be abbreviated to an FPD (Flat Panel Detector).

A radiation imaging apparatus capable of imaging static images for practical use includes FPDs provided with thin film semiconductors such as amorphous silicon on an insulating substrate made of material such as glass. The peripheral units such as a drive circuit unit and a signal processing circuit unit are included in an integrated circuit made of single crystalline semiconductor and are arranged in an insulating substrate. For such a radiation imaging apparatus, a large area FPDs of at least 40 square centimeters is already realized with technology of fabricating thin film semiconductor made of material such as amorphous silicon to cover the size of a human chest region. This fabrication process is comparatively simple. Therefore, realization of inexpensive radiation imaging apparatuses is being expected. Amorphous silicon can be fabricated on an insulating substrate such as made of thin glass of not more than 1 mm and, therefore, can be advantageously made extremely thin in thickness as a detector.

Recently, moving image pickup with such a radiation imaging apparatus is underway. Such an apparatus is expected to be fabricated inexpensively per unit so that image pickup of still images and moving images is disseminated to a lot of hospitals.

Such a radiation imaging apparatus with FPDs capable of image pickup of still images and moving images is described, for example, in Japanese Patent Application Laid-Open No. 2003-218339. Japanese Patent Application Laid-Open No. 2003-218339 discusses a pixel including a PIN photoelectric conversion element and an MIS photoelectric conversion element, a wavelength converter converting wavelength of radiation to light sensible by a photoelectric conversion element and a photoelectric conversion element converting light to electric charge and containing a conversion element generating electric signals corresponding to incident radiation. In addition, Japanese Patent Application Laid-Open No. 2003-218339 discusses an output switching element such as a thin film transistor (TFT) including main electrodes, one of which is connected to one of electrodes of the conversion element, so as to output electric signals based on electric charge generated by the conversion element. Japanese Patent Application Laid-Open No. 2003-218339 discusses an initializing switch element including main electrodes, one of which is connected to one of electrodes of the conversion element, so as to initialize the conversion element. As for Japanese Patent Application Laid-Open No. 2003-218339, one pixel includes at least one unit each of those conversion element, output switching element and initializing switch element. The converting unit includes those pixels arranged in a two dimensional matrix.

Japanese Patent Application Laid-Open No. 2003-218339 discusses output drive wiring provided to each row and connected commonly to a plurality of control electrodes of output switching elements arranged along the row in order to give output drive signals to each row. Japanese Patent Application Laid-Open No. 2003-218339 discusses initializing drive wiring provided to each row and connected commonly to a plurality of control electrodes of initializing switch elements arranged along the row in order to give initializing drive signals to each row. Those converting unit, bias wiring, output drive wiring, initializing drive wiring and signal wiring are arranged on an insulating substrate made of material such as glass by thin film semiconductor technology and are included in a sensor panel. The Patent Document 1 discusses one drive circuit unit each provided to output drive wiring and initializing drive wiring provided to each row so as to give output drive signals and initializing drive signals respectively. Moreover, each signal wiring includes at least one operational amplifier provided with a signal processing circuit unit (read out circuit unit) including a multiplexer converting parallel signals from a plurality of signal wirings to serial signals. This signal processing circuit unit reads out analog electric signals from a pixel. This signal processing circuit unit can include an A/D converter digitalizing analog electric signal and the A/D converter can be provided to the downstream stage of the signal processing circuit unit. Those drive circuit unit and signal processing circuit are single crystalline semiconductor integrated circuit (IC chips) made into chips and are arranged in a sensor panel to include electrical connection to the sensor panel. Consequently, outputting and read out operations and initializing operations of one of a conversion element and a pixel are enabled on each row.

However, radiation imaging apparatus described in Japanese Patent Application Laid-Open No. 2003-218339 is a mode with high wiring density since the output drive wiring and initializing drive wiring are both connected to one drive circuit unit on each pixel row. The imaging apparatus occasionally includes a sensor panel including a non-single crystalline semiconductor switching element as well as a conversion element and various wirings on an insulating substrate and a drive circuit unit being an IC chip, wherein the drive circuit unit is arranged in the sensor panel. Then, higher wiring density will increase electrical packaging density of the drive circuit unit. Consequently, higher wiring density with a small pixel pitch will hardly enable electrical packaging of the drive circuit unit.

Then, arranging initializing switch element of a predetermined row and an output switching element of the subsequent row so as to be connection to the same drive wiring, only one drive wiring will be satisfactory for one pixel row. However, in such a mode, the initializing operation of a predetermined row and the outputting operation of the subsequent row will be carried out simultaneously. Consequently, an output operation mode called pixel addition for simultaneously outputting the predetermined row and the subsequent row, for example, will be no longer feasible. That is, only output operation mode sequentially outputting on each row is feasible, giving rise to a problem of decreasing freedom on selection of the output operation mode.

Therefore, in Japanese Patent Application Laid-Open No. 2007-104219, for example, an output drive wiring is pulled out to a first side of a sensor panel to provide an output drive circuit unit and an initializing drive wiring is pulled out to a second side to provide the initializing drive circuit unit so that the first and second sides of the sensor panel sandwich a converting unit. With such configuration, electrical packaging density of a drive circuit unit per side is lower than the density in Japanese Patent Application Laid-Open No. 2003-218339 to reduce electrical packaging load on the drive circuit unit. Thus, freedom on selection on the output operation mode can be prevented from dropping.

### DISCLOSURE OF THE INVENTION

However, so-called shading occasionally takes place in the radiation imaging apparatus in Japanese Patent Application Laid-Open No. 2007-104219, giving rise to a problem that the originally regular analog electric signal output for each signal wiring arranged in plurality in the columnar direction gets uneven and, thereafter, density of the obtained image (signal output) gets uneven. The case where such shading takes place gives rise to a problem of occurrence of deviance of dynamic range of an A/D converter converting analog electric signal to digital electric signals, failing in acquisition of correct digital image data to decrease image quality.

The present invention has been attained in view of the above described problem. An object thereof is to provide an imaging apparatus and a radiation imaging system capable of simple electrical packaging of a drive circuit unit, securing freedom on selection of output operation mode and realizing acquisition of high quality image with reduced shading influence.

An imaging apparatus of the present invention includes a converting unit including a plurality of pixels arranged in a matrix on an insulating substrate, wherein the pixel comprises a conversion element having at least two electrodes and converting a radiation or a light into an electric signal, an output switching element having two main electrodes one of which is connected to one of the two electrodes of the conversion element for outputting the electric signal, and an initializing switch element having two main electrodes one of which is connected to the one of the two electrodes of the conversion element for initializing the conversion element; a first drive wiring connected electrically to control electrodes of the output switching elements of the pixels in a predetermined row; a second drive wiring connected electrically to control electrodes of the initializing switch elements of the pixels in a predetermined row; a third drive wiring connected electrically to control electrodes of the output switching elements of the pixels in the other row different from the predetermined row; a fourth drive wiring connected electrically to control electrodes of the initializing switch elements of the pixels in the other row; a first drive circuit unit arranged along a first side of the insulating substrate, and connected electrically to the first and second drive wirings; and a second drive circuit unit arranged along a second side of the insulating substrate arranged in opposition to the first side sandwiching the converting unit between the first and second sides, and connected electrically to the third and fourth drive wirings.

In addition, an imaging apparatus of the present invention includes a converting unit including a plurality of pixels arranged in a matrix on an insulating substrate, wherein the pixel comprises a conversion element having at least two electrodes and converting a radiation or a light into an electric signal, an output switching element having two main electrodes one of which is connected to one of the two electrodes of the conversion element for performing an outputting operation to output the electric signal, and a initializing switch element having two main electrodes one of which is connected to the one of the two electrodes of the conversion element, for initializing operation to initialize the conversion element; a first drive circuit unit arranged along a first side of the insulating substrate in order that the first drive circuit unit supplies a first output drive signal for performing the output operation to a control electrode of the output switching elements of the pixels in a predetermined row, and supplies a first initializing drive signal for performing the initializing operation to a control electrode of the initializing switch elements of the pixels in a predetermined row; and a second drive circuit unit arranged along a second side of the insulating substrate arranged in opposition to the first side sandwiching the converting unit between the first and second sides in order that the second drive circuit unit supplies a second output drive signal for performing the output operation to a control electrode of the output switching elements of the pixels in the other row different from the predetermined row, and supplies a second initializing drive signal for performing the initializing operation to a control electrode of the initializing switch elements of the pixels in the other raw different from the predetermined row.

The radiation imaging system of the present invention includes the above described imaging apparatus and a radiation generating unit for generating a radiation so as to impinge on an object, and then to be incident in the conversion element. The present invention enables simple electrical packaging of a drive circuit unit, secured freedom on selection of output operation mode and acquisition of high quality image with reduced shading influence.

Further features of the present invention will become apparent from the following description of exemplary embodiments with reference to the attached drawings.

### BRIEF DESCRIPTION OF THE DRAWINGS

FIG. 1 is a pattern diagram of a first embodiment of the present invention schematically including an imaging apparatus.

FIG. 2 is a flow chart exemplifying process procedure of an imaging apparatus related to a first embodiment of the present invention.

FIG. 3 is a timing chart illustrating a drive method in an operation mode 1 of an imaging apparatus related to the first embodiment of the present invention.

FIG. 4 is a timing chart illustrating a drive method in an operation mode 2 of an imaging apparatus related to the first embodiment of the present invention.

FIG. 5 is a timing chart illustrating a drive method in an operation mode 3 of an imaging apparatus related to the first embodiment of the present invention.

FIGS. 6A and 6B are pattern diagrams of a first embodiment of the present invention including the interior of a first drive circuit unit and exemplifying its drive timing.

FIG. 7 is a pattern diagram exemplifying wiring between a converting unit and respective drive circuit units and a read out circuit unit included in an imaging apparatus related to a first embodiment of the present invention.

FIG. 8 is a pattern diagram schematically including an imaging apparatus related to a conventional example.

FIG. 9 is a characteristic diagram exemplifying dark signals (FPN outputs) of an imaging apparatus related to a conventional example illustrated in FIG. 8.

FIG. 10 is a pattern diagram exemplifying wiring between a converting unit and respective drive circuit units and a read out circuit unit included in an imaging apparatus related to a second embodiment of the present invention.

FIGS. 11A and 11B are pattern diagrams exemplifying a third embodiment of the present invention including the interior of a first drive circuit unit and a second drive circuit unit.

FIG. 12 is a timing chart exemplifying the drive timing of the first drive circuit unit and the second drive circuit unit illustrated in FIGS. 11A and 11B.

FIG. 13 is a cross-sectional view of a fourth embodiment of the present invention schematically including one pixel included in a converting unit.

FIG. 14 is a pattern diagram of a fifth embodiment of the present invention schematically including a radiation imaging system.

### BEST MODES FOR CARRYING OUT THE INVENTION

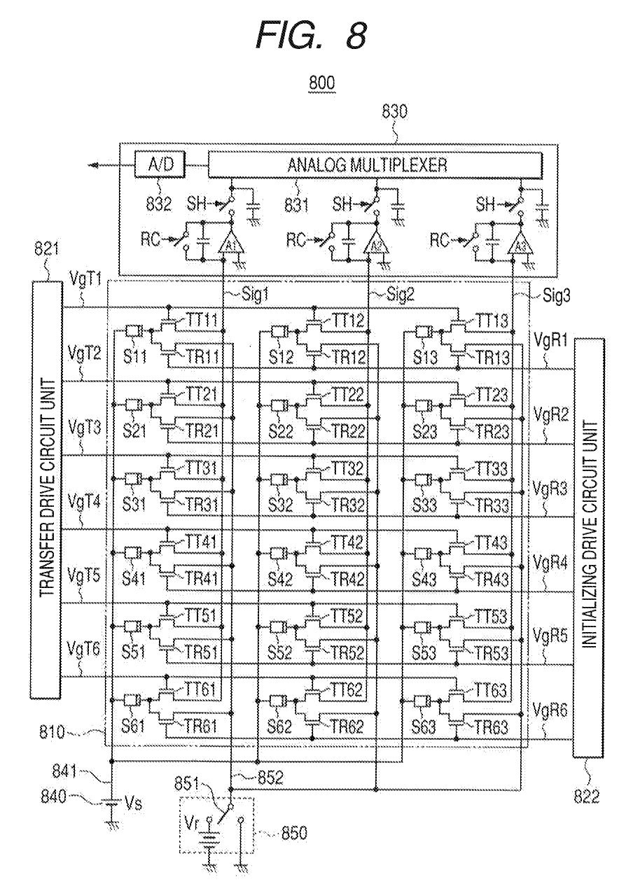

At first, the reason why shading occurs will be described. For a study, an imaging apparatus related to Japanese Patent Application Laid-Open No. 2007-104219 will be presented. FIG. 8 is a pattern diagram schematically including an imaging apparatus related to Japanese Patent Application Laid-Open No. 2007-104219.

A radiation imaging apparatus 800 illustrated in this FIG. 8 is provided with an output drive circuit unit 821 connected only to output drive wirings VgT1 to VgT6 and an initializing drive circuit unit 822 connected only to initializing drive wirings VgR1 to VgR6. For the following description, functions of a read out circuit unit 830, a sensor bias power supply 840, and an initializing power supply 850 illustrated in FIG. 8 are generally similar to functions of the read out circuit unit 130, the sensor bias power supply 140 and the initializing power supply 150 respectively and, therefore, to detailed description thereon will be omitted.

A radiation imaging apparatus 800 illustrated in FIG. 8 is connected to respective drive circuit units 821 and 822 so that an output drive wiring of an output switching element and an initializing drive wiring of an initializing switch element in the same row have the same wiring length in total. The drive circuit units are arranged to the left and the right of the converting unit 810 and are connected to generally the same number of drive wirings. The output drive circuit unit includes such components to solve a fabrication problem such as high packaging density of the drive circuit unit. However, the radiation imaging apparatus 800 illustrated in FIG. 8 gives rise to the following problems.

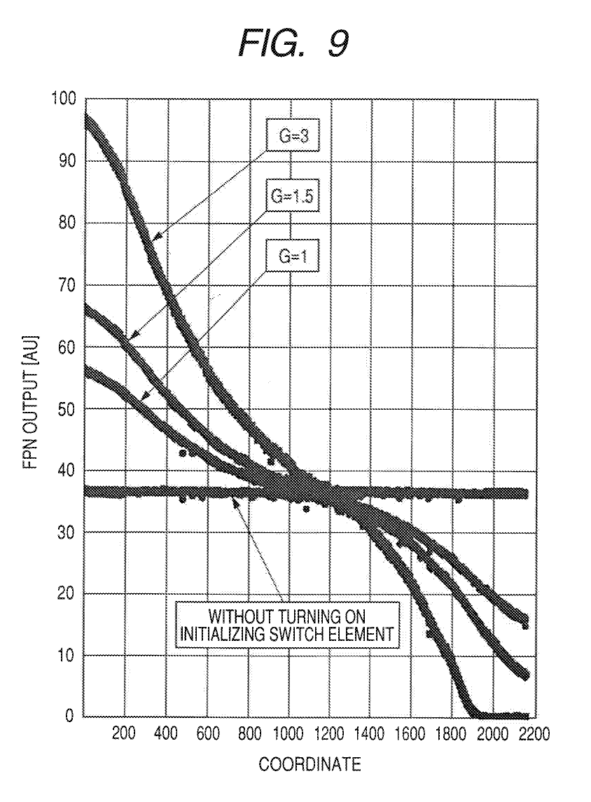

FIG. 9 is a characteristic diagram exemplifying dark signals (FPN outputs) of an imaging apparatus illustrated in FIG. 8. The axis of abscissas of this FIG. 9 is a column coordinate and illustrates the case where one row comprises 2156 pixels. The axis of ordinates in FIG. 9 has standardized dark signals (FPN outputs) from the read out circuit unit 830. The characteristic diagram in FIG. 9 illustrates property in the case where the gain inside the read out circuit unit 830 varies to 1, 1.5 and 3. As illustrated in FIG. 9, by changing the gain, the dark signal gets larger. If subtracting those dark signals from the output signals when radiation is impinged, the genuine output signal (genuine image signals) can be obtained.

However, as illustrated with the property with the gain being 3 in FIG. 9, the case where the dark signals on the lower side deviate from the dynamic range on the lower side of the A/D converter 832 gives rise to a problem that correct image signals are not obtained. In the cage of gain being 1.5 in FIG. 9, the dark signals are within the dynamic range of the A/D converter 832. However, at the coordinate 0 of the output switching element in the vicinity of the output drive circuit unit 821, the dark signal is approximately 62 (AU). That is, the dark signals (offset outputs) are desired to present a flat property without shading as illustrated with the gain in FIG. 9 being 1, 1.5 and 3.

FIG. 9 also illustrates dark signal property in the case of driving (a current flowing in) no initializing switch element. In that case, as illustrated in FIG. 9, the dark signal property is flat.

FIG. 9 illustrates the dark signal (FPN output) level being approximately 35 (AU) without shading. This is a level determined by the reference potential of the read out circuit unit 830 and the A/D converter 832 and is not abnormal in particular. This can be settled by subtraction process (compensation process).

In general, a finite dark current flows in the conversion element also in the dark state. Fluctuation occurs depending on the number of accumulated charge of that current. This fluctuation occurs at random in each pixel and is called shot noise being noise due to granularity of images. Thermal noise (Johnson noise) due to on resistance of the switching element and resistance values of signal wirings and drive wirings also occurs. This noise occurs at random in each pixel likewise the above described shot noise. Random noise also occurs in the read out circuit unit 830. Quality (image quality) of image varies according to thermal noise and 1/f noise due to transistors included in preamplifiers A1 to A3 and, in particular, initial-stage differential pair of transistors in an amplifier. Quantization noise in the A/D converter will be random noise. That is, as a unit of reducing appeared noise occurring in conversion elements and switching elements, the gains of the preamplifiers A1 to A3 are increased. The noise such as shot noise and thermal noise occurs independently in the respective components in developmental processes. Their total noise amount is expressed by square-root of sum of squares.

On the other hand, the signal amount is proportionate to the gains of the preamplifiers A1 to A3 of the read out circuit unit 830. That is, as illustrated in FIG. 9, in the case where the gain is set to 3, for example, the gain is twice larger than the gain being set to 1.5 and, therefore, the signal amount will be twice larger. However, since the noise amount of the read out circuit unit 830 will not be zero in principle, the total noise amount will not be twice larger. A reason thereof is presence of noise source generating random noise also in the subsequent stages of the preamplifiers A1 to A3. That is, S/N with the gain being set to 3 is larger than S/N with the gain being set to 1.5. In particular, in order to reduce the amount of radiation impinging on an object (patient) in the case of fluorography to pick up a plurality of sheets of images continuously, the gains of the preamplifiers A1 to A3 of the read out circuit unit 830 are desirably set larger.

However, the dark signal property illustrated in FIG. 9 includes shading property with a large offset output inside the relevant radiation imaging apparatus 800. Therefore, with the larger gain, offset output shading can deviate from the dynamic range of the A/D converter. Therefore, the gain occasionally might not be allowed to be set larger for fluorography. That is, the radiation imaging apparatus 800 illustrated in FIG. 8 cannot pick up X-ray images with good S/N ratio, giving rise to a problem that the amount of radiation impinging on an object (patient) cannot be reduced.

Subsequently, the cause of shading of the dark signal illustrated in FIG. 9 will be described below.

At first, the output operation only of the output switching element will be considered. Each time when a drive signal is switched between the on potential (high potential) and the off potential (low potential), the charge for that potential variation component flows to the node where the conversion element and the output switching element are brought into connection through the gate capacitance of the output switching element. While a current flows in the output switching element, the above described node stays at a certain constant potential. However, when no current flows, the potential variation component is retained through the gate capacitance when no current flows at the above described node. This potential variation component will be read out basically as dark offset signal when a current flows in the output switching element next (that is, subsequent frame). However, in that case, when a current flows in the output switching element in the subsequent frame, the potential variation component due to the on potential and the potential variation component due to the off potential cancel each other, giving rise to no offset output. That is, if the output drive signal to the output switching element is the similar rectangular wave whether or not a current flows, no offset output is considered to be generated (despite distance from the output drive circuit unit 821). That is, if only the output switching element is driven but no initializing switch element is driven, no shading occurs in the offset output as illustrated in FIG. 9.

Next, the case of driving both of the output switching element and the initializing switch element will be considered. In that case, a current flows in the subsequent initializing switch element and, thereby, the electric signal (charge) retained in the above described node flows in when the output switching element is put off is rest and will never be read out. Thereafter, the electric signal (charge) flowing in when the initializing switch element is put off is retained in the above described node and will be read out when a current flows in the output switching element in the subsequent frame. Based on this principle, when no current flows in the initializing switch element of a pixel near the output drive circuit unit 821 located along the left side of the converting unit 810, the pulse waveform (falling) is supplied from the distant initializing drive circuit unit 822 located along the right side of the converting unit 810 and, therefore, will lose sharpness. On the other hand, when a current flow in the output switching element of the relevant pixel, the pulse waveform (rising) is supplied from the nearby output drive circuit unit 821 and is, therefore, a rectangular wave is sharp.

The charge amount flowing in through the gate capacitance depends on the pulse waveform of the drive signal and, therefore, is not influential over the waveform lacking in sharpness. Accordingly, the pixel located on the left of the converting unit 810 will be significantly influenced by the rising pulse of the drive signal of the output switching element and will be a dark signal on the “+” side. On the other hand, on the contrary, the dark signal of the pixel located on the right of the converting unit 810 is dominantly influenced by the falling pulse of the drive signal of the initializing switch element and will be a dark signal on the “−” side. The dark signal in the pixel in the vicinity of the center of the converting unit 810 will be set off to become a balanced dark signal.

Shading in dark signal (offset output) property in FIG. 9 is caused by difference between signal waveform of the drive signal of the output drive wiring controlling the output switching element and signal waveform of the drive signal of the initializing drive wiring controlling the initializing switch element. More specifically, the reason thereof is that the potential variation component (charge) amount flowing into the node bringing the output switching element and the initializing switch element into connection when the drive signal varies in potential such as in the case of one of falling and rising is different according to the row direction.

The signal waveforms of the drive signal applied to those drive wirings depend on the resistance value of the drive wiring and the interelectrode capacitance of the switching element and, for the embodiment hereof, on the parasitic capacitance (Cgs, Cgd) between the gate electrode (G) of the TFT and one of the drain electrode (D) and the source electrode (S). The resistance of the drive wiring is caused by the materials of the drive wirings, their wiring widths and film thicknesses. Reduction of sharpness of the signal waveform is smaller as the resistance value is smaller. Reduction of sharpness of the signal waveform is also smaller as the interelectrode capacitance of the switching element is smaller. The reduction of sharpness of the signal waveform also refers to the falling property of the rising property and time delay related to lengths of the wirings.

The effective pixel region of the radiation imaging apparatus is frequently compliant to a general roentgen film. The half-cut size will be large with the approximate size of 35 cm×43 cm. This size is required for picking up an image of the human chest region. The physical size of the western people is larger than the physical size of Japanese people. The radiation imaging apparatus with an effective pixel region of 43 cm×43 cm is realized for practical use. The main material of such a large radiation imaging apparatus as the conversion element is non-single crystalline semiconductor material such as amorphous selenium and amorphous silicone. A thin film transistor (TFT) mainly made of non-single crystalline semiconductor material such as amorphous silicone as a main material is formed on an insulating substrate such as a glass substrate for use as the output switching element and the initializing switch element. Materials such as aluminum, molybdenum, chrome and tantalum are mainly used as the material of the TFT drive wiring.

In the case of such a large radiation imaging apparatus, the length of the drive wiring driving the TFT is not less than 43 cm and is extremely large. Necessarily, the resistance value of the drive wiring will get high. In general, the optical sensor made of the single crystalline semiconductor material such as single crystalline silicone CMOS sensor, MOS sensor and CCD are restricted by the wafer size. Therefore, it is not possible to manufacture a large sensor of 43 cm×43 cm, for example, with one wafer. In general, in the case where the radiation imaging apparatus includes the sensor manufactured from a single crystalline semiconductor wafer, it is considered to carry out one of image forming with a small chip through a shrinkage optical system and planning to attain an extended area with a plurality of small chips aligned.

However, wiring length of the switching element is shorter and the resistance value of the wiring is smaller than those of the radiation imaging apparatus with the switching element made of non-single crystalline semiconductor material. In general, mobility of the single crystalline silicone is known to be larger than non-single crystalline semiconductor such as amorphous silicone by approximately two to three digits. The size of a channel can be made small in the case where the switching element such as an MOS transistor and the switching element made of non-single crystalline semiconductor material include the equivalent property with a single crystalline semiconductor material such as single crystalline silicon. Consequently, the interelectrode capacitance of the switching element made of single crystalline semiconductor can be made extremely smaller than the interelectrode capacitance of the switching element made of non-single crystalline semiconductor such as TFT made of amorphous silicone. The single crystalline semiconductor in general is higher than the non-single crystalline semiconductor such as made of amorphous silicone in accuracy of process rules. Therefore, a channel can be formed in self alignment and the interelectrode capacitance can be made small.

In general, the size of the imaging element is small in a sensor made of the single crystalline semiconductor. Therefore, the gate wiring is short and the resistance value is small. Moreover, due to large mobility, the size of the switching element can be smaller than the size of the switching element made of the non-single crystalline semiconductor dramatically. Thus, the parasitic interelectrode capacitance of the gate wiring is small. Consequently, little shading occurs in the dark signal (offset) as in FIG. 9 of the sensor made of the single crystalline semiconductor. The influence of occasional occurrence is small. That is, the above described problem can be a problem peculiar to the radiation imaging apparatus with a switching element made of non-single crystalline semiconductor such as amorphous silicon TFT. That is, the above described problem occurs in the case where a large area radiation imaging apparatus includes thin film semiconductor such as an amorphous silicone TFT capable of extending the area by diverting process technology.

The inventor of the present invention found out that density (signal output) unevenness in an obtained image occurring in the radiation imaging apparatus 800, that is, so-called shading was caused by shading occurring in the dark signal (Offset). As a result of keen examination, the inventor of the present invention found out that the present invention including embodiments to be described below can solve shading occurring in images due to shading in the dark signal (offset).

### First Embodiment

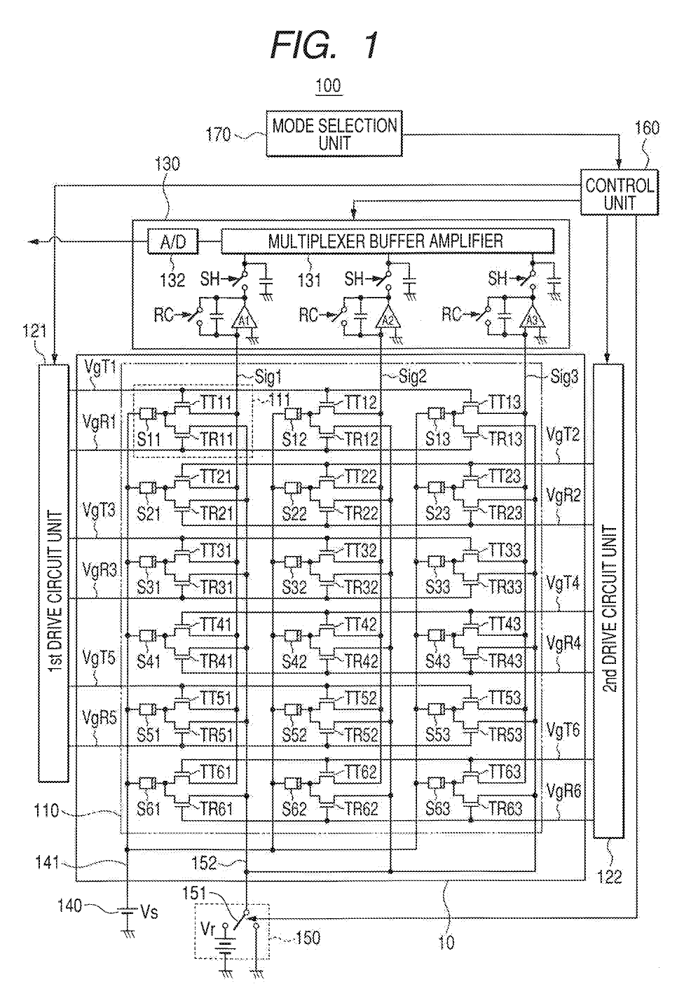

A first embodiment of the present invention will be described below with the accompanying drawings. FIG. 1 is a pattern diagram of a first embodiment of the present invention schematically including an imaging apparatus.

As illustrated in FIG. 1, a radiation imaging apparatus 100 includes a converting unit 110, a first drive circuit unit 121 and a second drive circuit unit 122, a read out circuit unit 130, a sensor bias power supply 140, an initializing power supply 150, a control unit 160 and a mode selection unit 170.

The converting unit 110 is formed to include a plurality of a pixel 111 being arranged in two-dimensional matrix on an insulating substrate (on a glass substrate 10 illustrated in FIG. 1). One pixel 111 is formed to include one conversion element (one of S11 to S63), one output switching element (one of TT11 to TT63) and one initializing switch element (one of TR11 to TR63). For convenience, the portion of 18 pixels of six rows× three columns in total of the pixel 111 is illustrated in the converting unit 110 in FIG. 1. However, naturally, further more pixels 111 can be arranged in a two-dimensional matrix and are formed.

The conversion elements S11 to S63 convert one of an incident radiation and an incident light to charges. Output switching elements TT11 to TT63 output electric signals based on charge converted by the respective conversion elements S11 to S63 to outside the pixel 111. The initializing switch elements TR11 to TR63 initialize the respective conversion elements S11 to S63. A TFT (Thin Film Transistor) made of non-single crystalline semiconductor such as amorphous silicon is used for the output switching element and the initializing switch element.

A drain electrode being one of two main electrodes of each output switching element (one of TT11 to TT63) is electrically connected to one of electrodes of each conversion element (one of S11 to S63). The drain electrode of each initializing switch element (one of TR11 to TR63) is connected to one of electrodes of each conversion element (one of S11 to S63). The other electrode of each conversion element (one of S11 to S63) is electrically connected to the bias wiring 140. A bias voltage Vs is applied thereto from the sensor bias power supply 140 through the bias wiring 141. A source electrode being the other main electrode of two main electrodes of each output switching element (one of TT11 to TT63) is connected to each signal wiring (one of Sig1 to Sig3). Moreover, the source electrode being the other main electrode of two main electrodes of each initializing switch element (one of TT11 to TT63) is electrically connected to an initializing voltage wiring 152.

The radiation imaging apparatus 100 is provided with output drive wirings VgT1 to VgT6 electrically connecting gate electrodes being control electrodes of the output switching elements TT11 to TT63 in the respective pixels 111 in the row direction. The radiation imaging apparatus 100 is provided with initializing drive wirings VgR1 to VgR6 electrically connecting gate electrodes of the initializing switch elements TR11 to TR63 in the respective pixels 111 in the row direction.

Among the output drive wirings VgT1 to VgT6, the output drive wirings VgT1, VgT3 and VgT5 are electrically connected to the first drive circuit unit 121 and the output drive wirings VgT2, VgT4 and VgT6 are electrically connected to the second drive circuit unit 122. Among the initializing drive wirings VgR1 to VgR6, the initializing drive wirings VgR1, VgR3 and VgR5 are electrically connected to the first drive circuit unit 121 and the initializing drive wirings VgR2, VgR4 and VgR6 are electrically connected to the second drive circuit unit 122.

The output drive wirings VgT1 to VgT6 and the initializing drive wirings VgR1 to VgR6 illustrated in FIG. 1 will be considered in a general manner.

For example, with an odd number n and in the case where the output drive wirings electrically connected to the n-th row output switching element are the first drive wirings, the first drive wirings will be output drive wirings VgT1, VgT3 and VgT5 in the example illustrated in FIG. 1. With an odd number n and in the case where the initializing drive wirings electrically connected to the n-th row output switching element are the second drive wirings, the second drive wirings will be initializing drive wirings VgR1, VgR3 and VgR5 in the example illustrated in FIG. 1. In the present embodiment, a plurality of the n-th row pixels correspond to a plurality of pixels of a predetermined row in the invention of the present application. Similarly, with an odd number n and in the case where the output drive wirings electrically connected to the n+1-th row output switching element are the third drive wiring, the third drive wirings will be output drive wirings VgT2, VgT4 and VgT6 in the example illustrated in FIG. 1. With an odd number n and in the case where the initializing drive wirings electrically connected to the n+1-th row initializing switch element are the fourth drive wirings, the fourth drive wirings will be initializing drive wirings VgR2, VgR4 and VgR6 in the example illustrated in FIG. 1. In the present embodiment, a plurality of n+1-th row pixels correspond to a plurality of pixels on another row different from a predetermined row in the present invention. In this case, the first drive circuit unit 121 will be electrically connected to the first drive wiring and the second drive wiring. The second drive circuit unit 122 will be electrically connected to the third drive wiring and the fourth drive wiring.

The first drive circuit unit 121 is arranged along a first side (left side in the example in FIG. 1) of a glass substrate 10 being an insulating substrate. On the other hand, the second drive circuit unit 122 is arranged along a second side (right side in the example in FIG. 1) of a glass substrate 10 arranged in opposition to the first side sandwiching the converting unit 110 between the first and second sides. The first drive circuit unit 121 supplies the first drive wirings with output drive signals at predetermined timing and supplies the second drive wirings with initializing drive signals at predetermined timing based on the control signals from the control unit 160. In the present embodiment, the output drive signals and the initializing drive signals supplied from the first drive circuit unit 121 are corresponding to the first output drive signals and the first initializing drive signals respectively in the present invention. The second drive circuit unit 122 supplies the third drive wirings with output drive signals at predetermined timing and supplies the fourth drive wirings with initializing drive signals at predetermined timing based on the control signals from the control unit 160. In the present embodiment, the output drive signals and the initializing drive signals supplied from the second drive circuit unit 122 are corresponding to the second output drive signals and the second initializing drive signals respectively in the present invention.

The read out circuit unit (signal processing circuit unit) 130 reads electric signals being output from the respective output switching elements TT11 to TT63 through the respective signal wirings Sig1 to Sig3. The read out circuit unit 130 mainly includes preamplifiers A1 to A3, a sampling and holding circuit SH, an analog multiplexer buffer amplifier 131 and an A/D converter 132. The respective signal wirings Sig1 to Sig3 of the read out circuit unit 130 are electrically connected to the inputs of the preamplifiers A1 to A3 respectively. The respective preamplifiers A1 to A3 can reset the potentials of the respective wirings Sig1 to Sig3 to GND, for example, with the RC signals from the control unit 160.

As described above, the sensor bias power supply 140 applies a bias voltage Vs to the other electrodes of the respective conversion elements S11 to S63 through the bias wiring 141.

The initializing power supply 150 supplies the source electrodes of the respective initializing switch elements TR11 to TR63 with one of a refresh voltage Vr and a reset voltage (GND) through the initializing voltage wiring 152 at the time of initializing the respective conversion elements S11 to S63. The switch 151 of the initializing power supply 150 is switched based on the control signals from the control unit 160 so as to supply the respective initializing switch elements TR11 to TR63 with one of a refresh voltage Vr and a reset voltage (GND). Thereby, the charges of the respective conversion elements S11 to S63 undergo one of refreshing and resetting so as to initialize the respective conversion element S11 to S63.

The control unit 160 generally controls drive in the radiation imaging apparatus 100 in a supervising manner. In particular, the control unit 160 of the present embodiment controls the first drive circuit unit 121 and the second drive circuit unit 122 independently according to the operation mode selected by the mode selection unit 170 of the radiation imaging apparatus 100. At initializing the respective conversion elements S11 to S63, the control unit 160 drives the respective initializing switch elements TR11 to TR63 to cause the initializing power supply 150 to supply the other electrodes of the respective conversion elements S11 to S63 with one of a refresh voltage Vr and the reset voltage (GND).

The mode selection unit 170 selects, for example, one operation mode among a plurality of operation modes based on operation inputs from a user.

The radiation imaging apparatus 100 of the present embodiment is connected to the respective drive circuit units so that the resistance value of the output drive wirings of the output switching elements is approximately equal to the resistance value of the initializing drive wirings of the initializing switch elements in the pixels of the same row. That is, the respective drive wiring are connected to the respective drive circuit units so that, in the respective pixels, the lengths of the output drive wirings for connection to the output switching elements are approximately equal to the lengths of the initializing drive wirings for connection to the initializing switch elements. For example, the length of the output drive wiring VgT1 from the first drive circuit unit 121 up to the position for connection to the output switching element TT13 corresponding to the conversion element S13 is approximately equal to the length of the initializing drive wiring VgR1 up to the position for connection to the initializing switch element TR13. Thereby, the potential variation component caused by the fall of the initializing drive signal is approximately equal to the potential variation component caused by rising of the output drive signal. Therefore, shading of the obtained image due to shading of the dark signal (offset) can be reduced. The drive circuit units are arranged in the left and right opposite locations of the converting unit 110 and approximately the same number of drive wirings are connected thereto. Such components are included and are arranged and, thereby, alleviation on the connection pitches of the respective drive circuit units is intended. Therefore, in the present embodiment, reduction of shading of the obtained image due to shading of the dark signal (offset) and alleviation on the connection pitches of the respective drive circuit units can be attained simultaneously.

Next, specific operations of the radiation imaging apparatus 100 will be described.

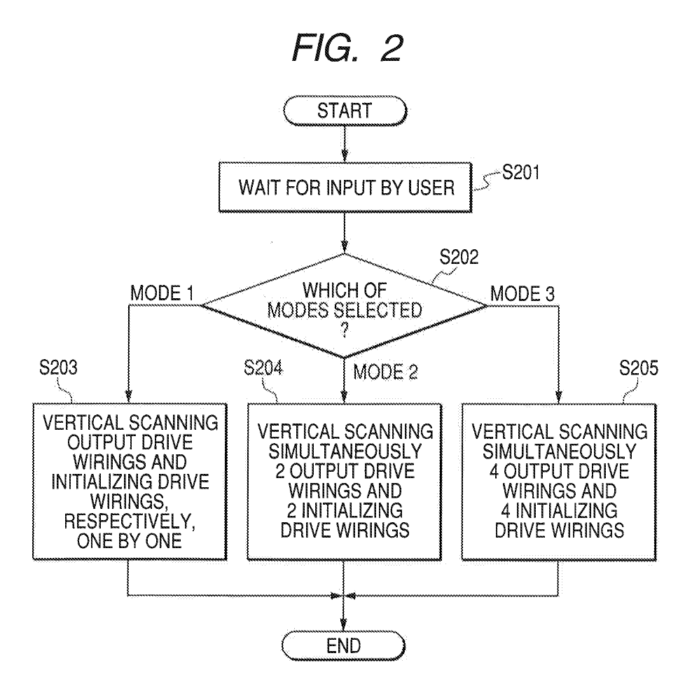

FIG. 2 is a flow chart exemplifying process procedure of an imaging apparatus related to a first embodiment of the present invention. The example illustrated in FIG. 2 illustrates the cases of the operation mode 1 to the operation mode 3 as operation modes being selectable by the mode selection unit 170. The radiation imaging apparatus 100 of the present embodiment includes a plurality of operation modes (three operation modes for the present embodiment) with different resolution as well as scanning speeds in the vertical scanning direction. The mode selection unit 170 selects and sets an operation mode related to a resolution as well as a scanning speed in the vertical scanning direction among three operation modes.

At first, in a step S201, the control unit 160 waits until a user carries out operations and inputs related to the operation mode.

Subsequently, in a step S202, when the user carries out operations and inputs related to an operation mode so that the mode selection unit 170 selects an operation mode. The control unit 160 determines what kind of mode the selected operation mode is.

In the case where the selected operation mode is an operation mode 1 as a result of determination in the step S202, the control unit 160 controls the first drive circuit unit 121 and the second drive circuit unit 122 and carries out the operation mode 1 in a step S203 so that the respective output drive wirings and the respective initializing drive wirings undergo vertical scanning one by one.

In the case of this step S203, specifically, the control unit 160 causes a current to flow in the output switching element of a predetermined row so as to output an electric signal corresponding to the charge of the corresponding conversion element to the read out circuit unit 130 and thereafter causes a current to flow in the initializing switch element of the same row. For example, a current is preferably caused to flow in the respective switching elements from the output drive wiring VgT1 to the initializing drive wiring VgR3 through the initializing drive wiring VgR1 through the output drive wiring VgT2 through initializing drive wiring VgT2, through output drive wiring VgT3 and so on. This operation mode 1 is an operation mode with the resolution being high and the scanning speed being slow since the respective output drive wirings and the respective initializing drive wirings undergo vertical scanning one by one.

In the case where the selected operation mode is an operation mode 2 as a result of determination in the step S202, the control unit 160 controls the first drive circuit unit 121 and the second drive circuit unit 122 and carries out the operation mode 2 in a step S204 so that two of the respective output drive wirings and two of the respective initializing drive wirings undergo vertical scanning simultaneously.

In the case of this step S204, the control unit 160 causes a current to flow in the first row and second row output drive wirings VgT1 and VgT2 connected to the output switching element simultaneously so as to control to read out an electric signal based on the charge of the corresponding conversion elements for two rows to the read out circuit unit 130. Thereafter, the control unit 160 causes a current to flow in the first row and second row initializing drive wirings VgR1 and VgR2 connected to the initializing switch element simultaneously so as to control to initialize the conversion elements for the corresponding two rows. This operation mode 2 is an operation mode with the resolution being middle and the scanning speed being middle speed since two of the respective output drive wirings and two of the respective initializing drive wirings undergo vertical scanning simultaneously.

In the case where the selected operation mode is an operation mode 3 as a result of determination in the step S202, the control unit 160 controls the first drive circuit unit 121 and the second drive circuit unit 122 and carries out the operation mode 3 in a step S205 so that four of the respective output drive wirings and four of the respective initializing drive wirings undergo vertical scanning simultaneously.

In the case of this step S205, specifically, the control unit 160 causes a current to flow in the first row to the fourth row output drive wirings VgT1 to VgT4 connected to the output switching element simultaneously so as to control to read out an electric signal corresponding to the charge of the corresponding conversion elements for four rows to the read out circuit unit 130. Thereafter, the control unit 160 causes a current to flow in the first row to fourth row initializing drive wirings VgR1 to VgR4 simultaneously so as to control to initialize the conversion elements for corresponding four rows. This operation mode 3 is an operation mode with the resolution being low and the scanning speed being rapid since four of the respective output drive wirings and four of the respective initializing drive wirings undergo vertical scanning simultaneously.

Thus, the control unit 160 controls the first drive circuit unit 121 and the second drive circuit unit 122 respectively so that the number of the drive wirings brought into electrical connection simultaneously is different at least for every operation mode selected by the mode selection unit 170.

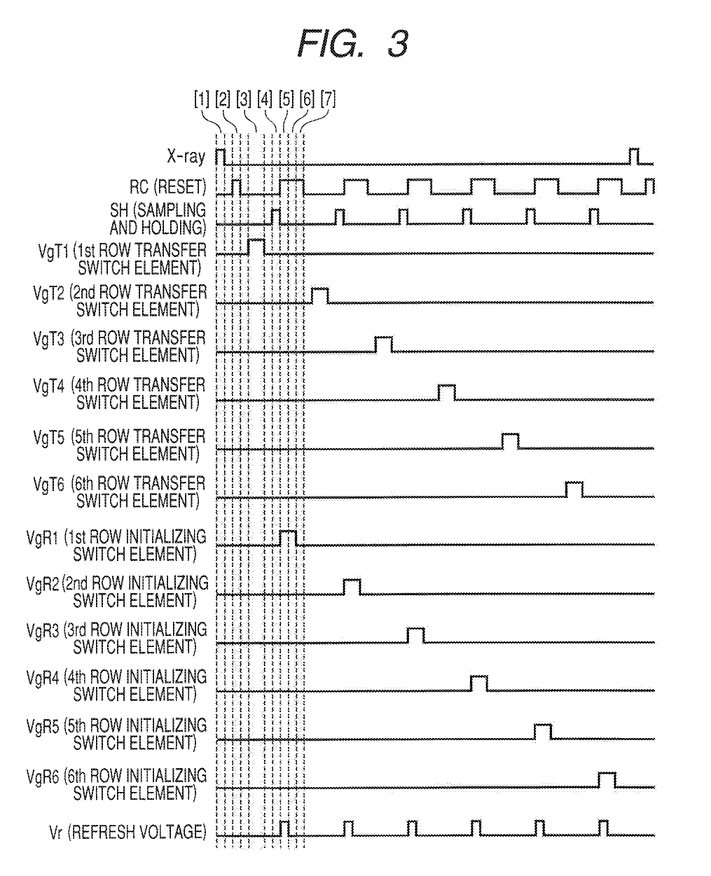

Subsequently, specific operations of units included in the radiation imaging apparatus 100 in the operation mode 1 to the operation mode 3 will be described with FIG. 3 to FIG. 5.

FIG. 3 is a timing chart illustrating a drive method in the operation mode 1 of an imaging apparatus related to the first embodiment of the present invention.

As described above, when the mode selection unit 170 selects the operation mode 1, the control unit 160 controls the first drive circuit unit 121 and the second drive circuit unit 122 so that the respective output drive wirings and the respective initializing drive wirings undergo vertical scanning one by one.

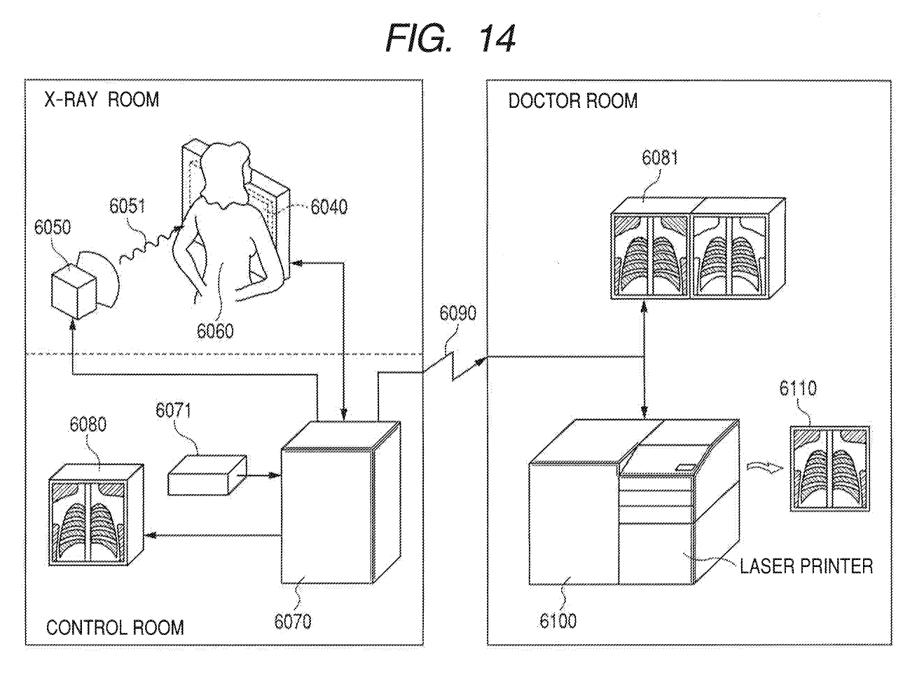

At first during a period [1] illustrated in FIG. 3, the control unit 160 controls, for example, an X-ray generating unit (radiation generating unit) 6050 illustrated in FIG. 14 to be described below and impinge on an object 6060 with pulse-like X-ray 6051. Thereby, the X-ray having transmitted through the object 6060 reaches the converting unit 110. An electric signal (charge) corresponding to the incident X-ray is accumulated in the respective conversion elements S11 to S63.

Subsequently, during a period [2], the control unit 160 supplies, for example, the read out circuit unit 130 with an RC signal (reset signal) and, thereby, sets the potentials of the respective signal wirings Sig1 to Sig3 to the GND potential and resets the integral capacitances of the preamplifiers A1 to A3.

Subsequently, during a period [3], the control unit 160 controls the first drive circuit unit 121 to apply an output drive signal to the first row output drive wiring VgT1 connected to the gate electrodes of the first row output switching elements TT11 to TT13. Thereby, the electric signals corresponding to the charges accumulated in the first row conversion elements S11 to S13 are read out in parallel by the read out circuit unit 130 through the respective signal wirings Sig1 to Sig3.

Subsequently, for example, the control unit 160 supplies the read out circuit unit 130 with an SH signal (sampling and holding signal) during a period [4]. Thereby, the parallel electric signals read out by the read out circuit unit 130 corresponding to the first row conversion elements S11 to S13 undergo sampling in the sampling and holding circuit SH and the analog multiplexer buffer amplifier 131 and are converted into serial analog signals.

Subsequently, during a period [5], the control unit 160 supplies the read out circuit unit 130 with the RC signal again so as to reset the integral capacitance of the preamplifiers A1 to A3 and simultaneously set the potentials of the respective signal wirings to GND so that currents flow in the first row initializing switch elements TR11 to TR13. Simultaneously, the control unit 160 causes the initializing power supply 150 to supply the respective initializing switch elements with refresh voltage Vr through the initializing voltage wirings 152 and thereby controls and refreshes the first row conversion elements S11 to S13. In that case, the first row conversion elements S11 to S13 are refreshed at the potential Vr on the individual electrode (one electrode) side.

Subsequently, during a period [6], the control unit 160 causes the initializing power supply 150 to supply a reset voltage (GND) through the initializing voltage wiring 152 in the state of supplying the RC signal and a current is flowing in the first row initializing switch element. Thereby, the potential on the individual electrode side of each conversion element reaches the GND potential so as to enable the conversion operation to the incident X-ray electric signal (charge).

Subsequently, during the period [7], the control unit 160 controls so that no current flows in the first row initializing switch elements TR11 to TR13. Thereby, the electrical field of each conversion element is retained so as to be capable of getting prepared for the conversion operations to the incident X-ray electric signal (charge). The period [7] is also a period, during which no current flows in the first row initializing switch elements TR11 to TR13 in operation, provided for alleviating the potential in order to get prepared for an output of the next electric signal (charge) in the case where the potential of the signal wiring fluctuates by coupling capacitance by the drive wiring and the signal wiring.

The output operations and refresh operations illustrated in the period [3] to the period [7] undergo scanning on all rows of drive wirings one by one (on the single row basis). Thereby, the electric signals (charges) of the respective conversion elements S11 to S63 of the entire converting unit 110 can be read out.

With this operation mode 1, as illustrated in FIG. 3, the control unit 160 controls the first drive circuit unit 121 to supply the output drive wiring VgT1 (first drive wiring) and the initializing drive wiring VgR1 (second drive wiring) with drive signals at different timings. The control unit 160 controls the second drive circuit unit 122 to supply the output drive wiring VgT2 (third drive wiring) and the initializing drive wiring VgR2 (fourth drive wiring) with drive signals at different timings.

The control unit 160 controls the first drive circuit unit 121 and the second drive circuit unit 122 to supply the output drive wiring VgT1 (first drive wiring) and the output drive wiring VgT2 (third drive wiring) with drive signals at different timings. The control unit 160 controls the first drive circuit unit 121 and the second drive circuit unit 122 to supply the initializing drive wiring VgR1 (second drive wiring) and the initializing drive wiring VgR2 (fourth drive wiring) with drive signals at different timings.

Peculiarly, resolution with this operation mode 1 is the highest among the three operation modes. On the other hand, since all of the drive wirings are scanned one by one, scanning requires time with respect to speed.

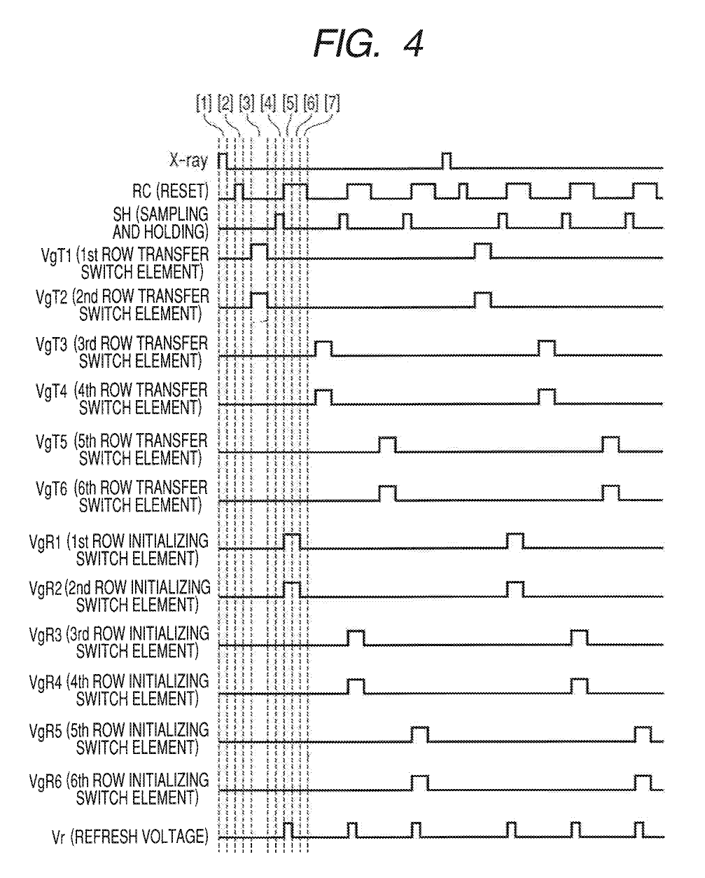

FIG. 4 is a timing chart illustrating a drive method in an operation mode 2 of an imaging apparatus related to the first embodiment of the present invention.

As described above, when the mode selection unit 170 selects the operation mode 2, the control unit 160 controls the first drive circuit unit 121 and the second drive circuit unit 122 so that every two output drive wirings at a time and every two initializing drive wirings at a time undergo vertical scanning.

At first during a period [1] illustrated in FIG. 4, the control unit 160 controls, for example, an X-ray generating unit (radiation generating unit) 6050 illustrated in FIG. 14 to be described below and impinge on an object 6060 with pulse-like X-ray 6051. Thereby, the X-ray having transmitted through the object 6060 reaches the converting unit 110. An electric signal (charge) corresponding to the incident X-ray is accumulated in the respective conversion elements S11 to S63.

Subsequently, during a period [2], the control unit 160 supplies, for example, the read out circuit unit 130 with an RC signal (reset signal) and, thereby, resets the potentials of the respective signal wirings Sig1 to Sig3 to the GND potential.

Subsequently, during a period [3], the control unit 160 controls the first drive circuit unit 121 and the second drive circuit unit 122 to apply output drive signals to the first row output drive wiring VgT1 and the second row output drive wiring VgT2 simultaneously. The first row output drive wiring VgT1 is connected to the gate electrodes of the first row output switching elements TT11 to TT13 and the second row output drive wiring VgT2 is connected to the gate electrodes of the second row output switching elements TT21 to TT23. Thereby, the electric signals (charges) accumulated in the first row conversion elements S11 to S13 and the second row conversion elements S21 to S23 are read out by the read out circuit unit 130 through the respective signal wirings Sig1 to Sig3. At this occasion, the respective electric signals (charges) in the respective group of the conversion elements S11 and S21, the conversion elements S12 and S22 and the conversion elements S13 and S23 are overlapped and read out by the read out circuit unit 130.

Subsequently, for example, the control unit 160 supplies the read out circuit unit 130 with an SH signal (sampling and holding signal) during a period [4]. Thereby, the electric signals (charges) overlapped and read out by the read out circuit unit 130 undergo sampling in the sampling and holding circuit SH and the analog multiplexer buffer amplifier 131 and are converted to serial analog signals.

Subsequently, during a period [5], the control unit 160 supplies the read out circuit unit 130 with the RC signal again so as to reset the integral capacitance of the preamplifiers A1 to A3 and simultaneously reset the potentials of the respective signal wirings to GND so that currents flow in the first row and second row initializing switch elements simultaneously. Simultaneously, the control unit 160 causes the initializing power supply 150 to supply the respective initializing switch elements with refresh voltage Vr through the initializing voltage wirings 152 and thereby controls and refreshes the first row and second row conversion elements S11 to S23. In that case, the first row and second row conversion elements S11 to S23 are refreshed at the potential Vr on the individual electrode side.

Subsequently, during a period [6], the control unit 160 causes the initializing power supply 150 to supply a reset voltage (GND) through the initializing voltage wiring 152 in the state of supplying the RC signal and currents are flowing in the first row and second row initializing switch elements. Thereby, the individual electrode side of each conversion element reaches the GND potential so as to enable the conversion operation to the incident X-ray electric signal (charge).

Subsequently, during the period [7], the control unit 160 controls so that no current flows in the first row and second row initializing switch elements TR11 to TR23. Thereby, the electrical field of each conversion element is retained so as to be capable of getting prepared for the conversion operations to the incident X-ray electric signal (charge). The period [7] is also a period, during which no current flows in the first row and second row initializing switch elements TR11 to TR23 in operation, provided for alleviating the potential in order to get prepared for an output of the next electric signal in the case where the potential of the signal wiring fluctuates by coupling capacitance by the drive wiring and the signal wiring.

The output operations and refresh operations illustrated in the period [3] to the period [7] undergo scanning on every two (every two rows) at a time for all rows of drive wirings. Thereby, the electric signals (charges) of the respective conversion elements S11 to S63 of the entire converting unit 110 can be read out.

In this operation mode 2, the control unit 160 controls, as illustrated in FIG. 4, the first drive circuit unit 121 to supply the output drive wiring VgT1 (first drive wiring) and the initializing drive wiring VgR1 (second drive wiring) with drive signals at different timings. The control unit 160 controls the second drive circuit unit 122 to supply the output drive wiring VgT2 (third drive wiring) and the initializing drive wiring VgR2 (fourth drive wiring) with drive signals at different timings.

In addition, the control unit 160 controls the first drive circuit unit 121 and the second drive circuit unit 122 to supply the output drive wiring VgT1 (first drive wiring) and the output drive wiring VgT2 (third drive wiring) with drive signals at the same timing. The control unit 160 controls the first drive circuit unit 121 and the second drive circuit unit 122 to supply the initializing drive wiring VgR1 (second drive wiring) and the initializing drive wiring VgR2 (fourth drive wiring) with drive signals at the same timing.

This operation mode 2 is inferior to the operation mode 1 since resolution is reduced more or less as every two drive wirings are scanned at a time but is superior thereto SNR-wise since the signal level rises to improve scanning speed with required time being reduced by half.

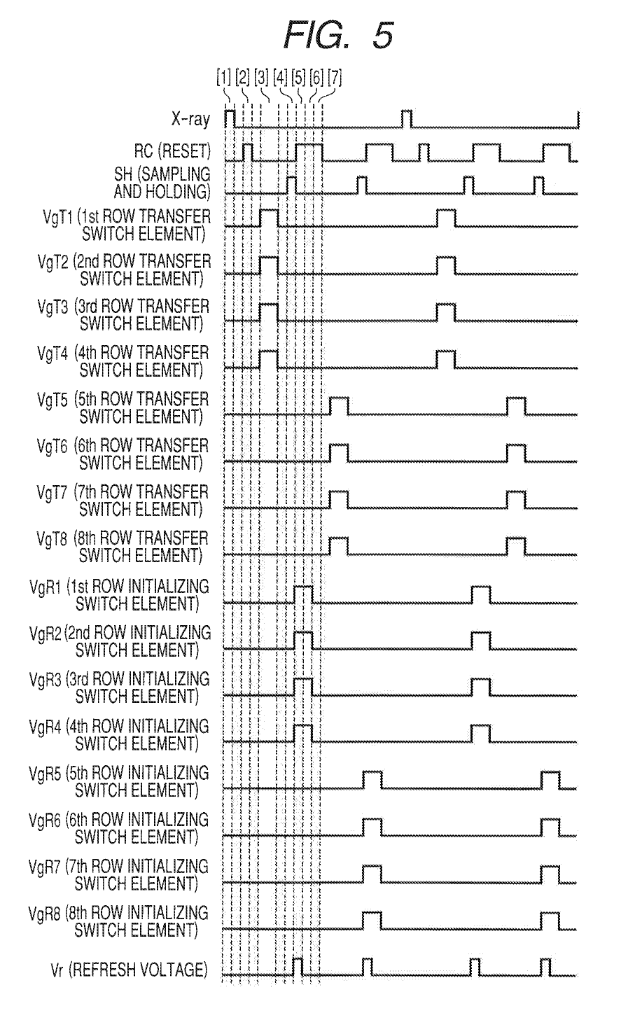

FIG. 5 is a timing chart illustrating a drive method in an operation mode 3 of an imaging apparatus related to the first embodiment of the present invention. In FIG. 5, timings for output drive wirings VgT7 and VgT8 as well as initializing drive wiring VgR7 and VgR8 not illustrated in FIG. 1 are also depicted for the sake of convenience.

As described above, when the mode selection unit 170 selects the operation mode 3, the control unit 160 controls the first drive circuit unit 121 and the second drive circuit unit 122 so that every four output drive wirings at a time and every four initializing drive wirings at a time undergo vertical scanning.

At first during a period [1] illustrated in FIG. 5, the control unit 160 controls, for example, an X-ray generating unit (radiation generating unit) 6050 illustrated in FIG. 14 to be described below and impinge on an object 6060 with pulse-like X-ray 6051. Thereby, the X-ray having transmitted through the object 6060 reaches the converting unit 110. An electric signal (charge) corresponding to the incident X-ray is accumulated in the respective conversion elements S11 to S63.

Subsequently, during a period [2], the control unit 160 supplies, for example, the read out circuit unit 130 with an RC signal (reset signal) and, thereby, resets the potentials of the respective signal wirings Sig1 to Sig3 to the GND potential.

Subsequently, during a period [3], the control unit 160 controls the first drive circuit unit 121 and the second drive circuit unit 122 to apply output drive signals to the first row and third row output drive wirings and the second row and fourth row output drive wirings simultaneously. Thereby, the electric signals based on charges accumulated in the first row to fourth row conversion elements S11 to S43 are read out by the read out in parallel circuit unit 130 through the respective signal wirings Sig1 to Sig3. At this occasion, the respective electric signals in the respective group of the conversion elements S11 to S41, the conversion elements S12 to S42 and the conversion elements S13 to S43 are overlapped and read out by the read out circuit unit 130.

Subsequently, for example, the control unit 160 supplies the read out circuit unit 130 with an SH signal (sampling and holding signal) during a period [4]. Thereby, the electric signals (charges) overlapped and read out by the read out circuit unit 130 undergo sampling in the sampling and holding circuit SH and the analog multiplexer buffer amplifier 131 and are converted to serial analog signals.

Subsequently, during a period [5], the control unit 160 supplies the read out circuit unit 130 with the RC signal again so as to reset the integral capacitance of the preamplifiers A1 to A3 and simultaneously set the potentials of the respective signal wirings to GND so that currents flow in the first row to fourth row initializing switch elements simultaneously. Simultaneously, the control unit 160 causes the initializing power supply 150 to supply the respective initializing switch elements with refresh voltage Vr through the initializing voltage wirings 152 and thereby controls and refreshes the first row to fourth row conversion elements S11 to S43. In that case, the first row to fourth row conversion elements S11 to S43 are refreshed at the potential Vr on the individual electrode side.

Subsequently, during a period [6], the control unit 160 causes the initializing power supply 150 to supply a reset voltage (GND) through the initializing voltage wiring 152 in the state of supplying the RC signal and currents are flowing in the first row to fourth row initializing switch elements. Thereby, the individual electrode side of each conversion element reaches the GND potential so as to enable the conversion operation to the incident X-ray electric signal (charge).

Subsequently, during the period [7], the control unit 160 controls so that no current flows in the first row to fourth row initializing switch elements TR11 to TR43. Thereby, the electrical field of each conversion element is retained so as to be capable of getting prepared for the conversion operations to the incident X-ray electric signal (charge).

The output operations and refresh operations illustrated in the period [3] to the period [7] undergo scanning on every four (every four rows) at a time for all rows of drive wirings. Thereby, the electric signals (charges) of the respective conversion elements of the entire converting unit 110 can be read out.

This operation mode 3 is inferior to the operation modes 1 and 2 since resolution is reduced further as every four drive wiring are scanned at a time but is superior thereto SNR-wise since the signal level rises further. With respect to scanning speed, required time will be reduced to a quarter compared to the operation mode 1 so as to improve the speed further.

Next, the interiors included in the first drive circuit unit 121 and the second drive circuit unit 122 and the drive timings thereof will be described.

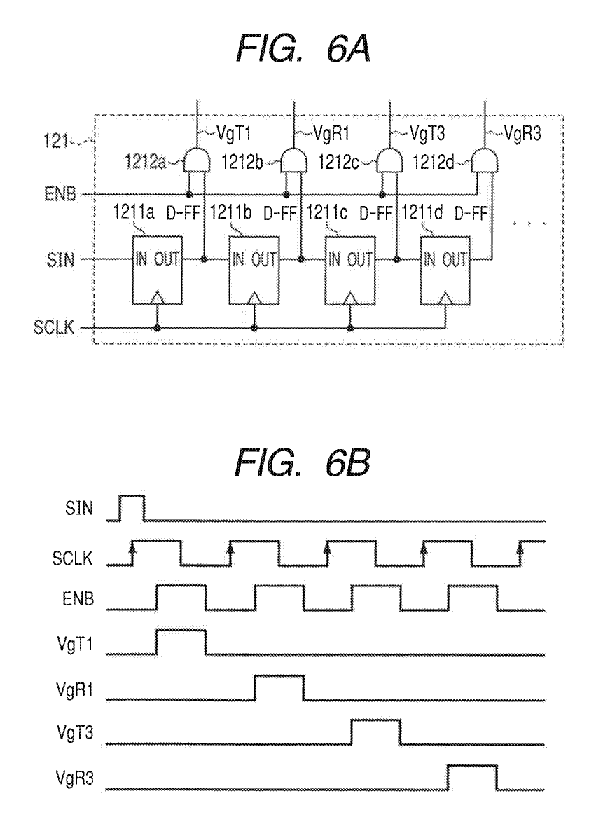

FIGS. 6A and 6B are pattern diagrams of the first embodiment of the present invention including the interior of a first drive circuit unit and exemplifying its drive timing. FIGS. 6A and 6B illustrate the first drive circuit unit 121 for the sake of convenience. The second drive circuit unit 122 is likewise as well.

As illustrated in FIG. 6A, the first drive circuit unit 121 includes D flip-flops (1211a to 1211d) and AND gates (1212a to 1212d). The first drive circuit unit 121 is controlled by SIN signals (start pulse signals), SCLK signals (shift clock signals) and ENB signals (enable signals) supplied by the control unit 160. FIG. 6B illustrates drive timings of the first drive circuit unit 121 illustrated in FIG. 6A.

In the case where the first drive circuit unit 121 and the second drive circuit unit 122 include shift registers illustrated in FIG. 6A, the control unit 160 supplies, for example, the respective drive circuit units with different SIN signals, SCLK signals and ENB signals.

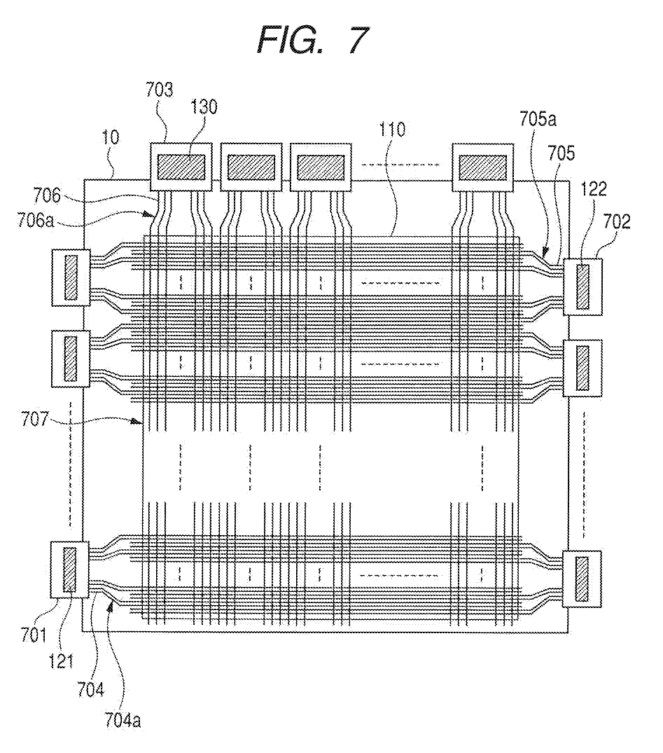

FIG. 7 is a pattern diagram exemplifying wiring between a converting unit and respective drive circuit units and a read out circuit unit included in an imaging apparatus related to a first embodiment of the present invention. In FIG. 7, a glass substrate 10 being an insulating substrate is illustrated. A converting unit 110 and the respective wirings are formed on this glass substrate 10.

As illustrated in FIG. 7, a plurality of first drive circuit units 121 made of, for example, IC are arranged along the left side (first side) of the glass substrate 10. The first drive circuit units 121 are mounted on a flexible base (flexible wiring plate) 701 made of, for example, polyimide being the main material. A plurality of second drive circuit units 122 made of, for example, IC are arranged along the right side (second side) of the glass substrate 10. The second drive circuit units 122 are mounted on a flexible base 702 made of, for example, polyimide being the main material.

A plurality of read out circuit units 130 made of, for example, IC are arranged along the upper side of the glass substrate 10. The read out circuit units 130 are mounted on a flexible base 703 made of, for example, polyimide being the main material.

The respective bases 701 to 703 respectively comprise the first drive circuit unit 121, the second drive circuit unit 122, the read out circuit unit 130 and the wiring for bringing the respective types of wirings on the glass substrate 10 into connection although not illustrated in the drawing.

A drive wiring 704, a drive wiring 705 and a signal wiring 706 are formed on the glass substrate 10, where a drive wiring 704 brings the converting unit 110 and the first drive circuit unit 121 into connection; a drive wiring 705 brings the converting unit 110 and the second drive circuit unit 122 into connection; and a signal wiring 706 brings the converting unit 110 and the read out circuit unit 130 into connection. In appearance, the drive wiring 704 is illustrated to be bent in the wiring unit 704a of the drive wiring 704. The bent region has undergone pitch conversion since the pixel pitch of the converting unit 110 is different from the connection pitch of the first drive circuit unit 121. The wiring unit 705a of the drive wiring 705 and the wiring unit 706a of the signal wiring 706 are likewise as well. The position 707 is illustrated to be located in region where the converting unit 110 is formed in the vicinity of the center of the vertical direction.

The first drive circuit unit 121, the second drive circuit unit 122 and the read out circuit unit 130 are formed in the normal semiconductor process. In the case where a radiation imaging apparatus 100 is applied as an X-ray imaging apparatus for medical use, the converting unit 110 requires the imaging region of approximately 40 square centimeters in order to pick up an image of the chest region of an object. In this case, the first drive circuit unit 121, the second drive circuit unit 122 and the read out circuit unit 130 are substantially formed such as of a plurality of ICs as illustrated in FIG. 7. A large number of those components are obtained from a semiconductor wafer manufactured, for example, in a CMOS process.

For the radiation imaging apparatus 100 as illustrated in FIG. 7, the read out circuit unit 130 is formed only along a side of a glass substrate 10 and, therefore, is cost-wise advantageous. In the read out circuit unit 130, preamplifiers (A1 to A3) are desired to be connected to the respective signal wirings as illustrated in FIG. 1. In order to reduce noise of the preamplifiers (A1 to A3) connected to each column of pixels of the converting unit 110 through the respective signal wirings, the transistors included in the relevant preamplifier initial-stage differential pair are desired to be sized large. However, in that case, the IC chip area included in the read out circuit unit 130 gets large to increase fabrication costs. The consumed power gets large.

As illustrated in FIG. 7, the read out circuit unit 130 is formed only along one side of the glass substrate 10 so that the signal wiring is pulled only to the relevant side. Thereby the fabrication cost is advantageously reduced so that the consumed power can be significantly alleviated. Formation of the read out circuit unit 130 only along one side of the glass substrate 10 and reduction in number of the read out circuit unit 130 can reduce inclusion of, for example, memory included in a unit and connected to the subsequent stage can be reduced, giving rise to subsidiary cost reduction and reduction of consumed power and weight saving on the apparatus.

As illustrated in FIG. 7, no read out circuit unit 130 is formed along the lower side of the glass substrate 10. Therefore, the converting unit 110 can be arranged up to the vicinity of the lower side of the glass substrate 10. Consequently, the imaging region can peculiarly cover the lung field side of the breast widely in the case of picking up an image by pushing the imaging region of the radiation imaging apparatus 100 below the breast in, for example, mammography.

The first row output drive wiring VgT1 is connected to the first drive circuit unit 121 in FIG. 7 and the first row initializing drive wiring VgR1 is likewise connected to its next stage as illustrated in FIG. 1. The third row output drive wiring VgT3 is connected to the next stage of the first drive circuit unit 121 and the third row initializing drive wiring VgR3 is likewise connected to its next stage. Thus, the first drive circuit unit 121 is connected to two drive wirings corresponding to the odd-numbered rows. Similarly, the second drive circuit unit 122 in FIG. 7 is connected to two drive wirings corresponding to even-numbered rows as illustrated in FIG. 1.

Thus, the respective drive wirings are brought into connection. Thereby, approximately the same number of drive wirings will be connected to the first drive circuit unit 121 and the second drive circuit unit 122. Wirings such as the bias wiring 141 and the initializing voltage wiring 152 are omitted in FIG. 7.

The radiation imaging apparatus 100 of the present embodiment is connected to the respective drive circuit units so that the resistance values of the output drive wirings of the output switching elements will be roughly equal to those of the initializing drive wiring of the initializing switch elements along the same row, that is, the lengths are roughly equal. In addition, the drive circuit unit is arranged in the left and right opposite positions of the converting unit 110 and roughly the same number of drive wirings are connected thereto. Thereby, alleviation of the connection pitches of the respective drive circuit units is aimed.

As described above, according to the radiation imaging apparatus 100 of the present embodiment, with the simple implementation of connecting the output drive wiring and the initializing drive wiring along the same row to one of the first drive circuit unit 121 and the second drive circuit unit 122, an image with high quality subjected to reduction of shading influence can be obtained. The output drive wirings and the initializing drive wirings along the odd-numbered row are connected to the first drive circuit unit 121. The output drive wirings and the initializing drive wirings along the even-numbered row are connected to the second drive circuit unit 122. Therefore, freedom of selection of the output operation mode can be secured. Consequently, for example, in the case where any one of the operation mode 1 to the operation mode 3 illustrated in FIG. 3 to FIG. 5 is selected by the mode selection unit 170, the operation can also be carried out smoothly. Imaging of a radiation image subjected to variation of resolution and scanning speed in the vertical scanning direction can be realized. The present invention can also give rise to a dramatic effect to a large area radiation imaging apparatus with switching elements made of non-single crystalline semiconductor.

The control unit 160 of the present embodiment controls the number of vertical scanning of the first drive circuit unit 121 and the second drive circuit unit 122 performed at a time. However, not only the relevant number is controlled but, for example, the drive signal pulse length can be controlled.

Wiring diagrams in FIG. 7 exemplifies components included in the present embodiment. For example, the first drive circuit unit 121 can be connected to the first row, second row, fifth row, sixth row, . . . drive wirings. The second drive circuit unit 122 can be connected to the third row, fourth row, seventh row, eighth row, . . . drive wirings. In this case, if remarkable non uniformity occurs in connection of the drive wiring to the respective drive circuit units, such connection will not change the essential quality of the present invention.

In the present embodiment, the operation mode 1 to the operation mode 3 are described as selectable operation mode in the mode selection unit 170. More operation modes can be adopted for setting.

### Second Embodiment

A second embodiment of the present invention will be described below with the accompanying drawings. The components roughly included in the radiation imaging apparatus related to the second embodiment of the present invention are similar to the components roughly included in the radiation imaging apparatus 100 related to the first embodiment illustrated in FIG. 1.

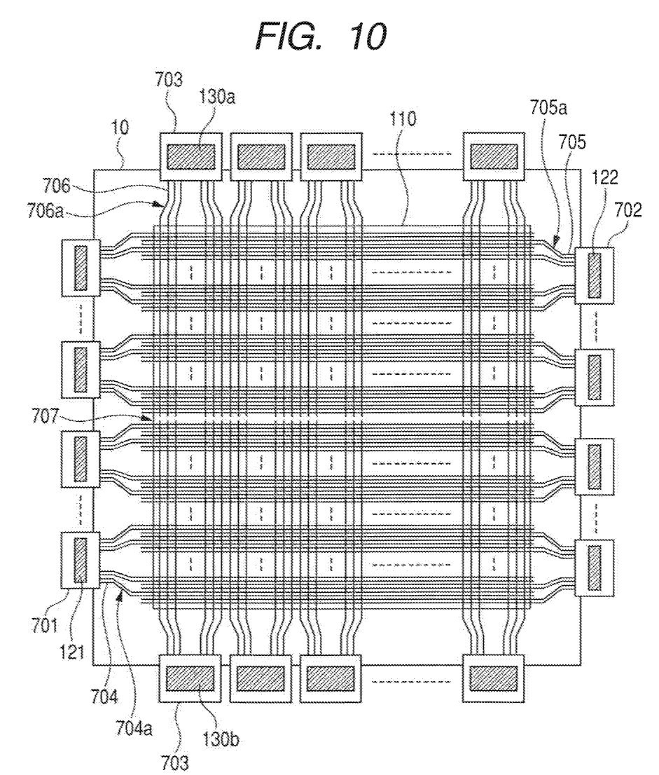

FIG. 10 is a pattern diagram exemplifying wiring between a converting unit and respective drive circuit units and a read out circuit unit included in an imaging apparatus related to a second embodiment of the present invention. In FIG. 10, the same reference symbols designate the same components included in FIG. 7.

FIG. 10 is different from FIG. 7 in the point that the read out circuit unit is formed as the read out circuit units 130a and 130b along the both upper side and lower side of the glass substrate 10. In FIG. 7, the signal wirings are brought into connection for all rows from the upper side to the lower side of the converting unit 110. In contrast, in FIG. 10, the signal wirings are split in the position 707 in the vicinity of the center of the vertical direction of the region where the converting unit 110 is formed.

In the second embodiment, the read out circuit units 130a and 130b are arranged along the both sides of the upper side and the lower side of the glass substrate 10. Therefore, cost-wise, the second embodiment in FIG. 10 is more disadvantageous than the first embodiment in FIG. 7. However, random noise can be made smaller. In particular, the radiation imaging apparatus for medical use requires high S/N. Therefore, the preamplifiers A1 to A3 are desired to be connected to the signal wirings respectively for noise reduction as illustrated in FIG. 1. The reason thereof is to decrease influence of random noise to an image due to conversion elements, switching elements and wirings included in a pixel.

In FIG. 10, the signal wirings are half shorter than the signal wirings in FIG. 7. Therefore, the resistance values of the signal wirings are half smaller. Thereby, the thermal noise of the wirings can be reduced. The parasitic capacitance values of the signal wirings in FIG. 10 are half smaller than the values in FIG. 7. Reduction by half on this capacitance can decrease amplifying level of noise of the preamplifiers A1 to A3 and consequently contributes to decrease of total random noise.

The second embodiment will be more advantageous in operation speed since the read out circuit units 130a and 130b are arranged along the both sides of the upper side and the lower side of the glass substrate 10 and, therefore, the upper region and the lower region of the converting unit 110 can be caused to operate in parallel. Consequently, in planning, the operation speed of the second embodiment can be twice faster than that of the radiation imaging apparatus illustrated in FIG. 7. Thus, the radiation imaging apparatus including the components is preferably embodied in consideration of balance such as on fabrication cost, performance and convenience for use.

### Third Embodiment

A third embodiment of the present invention will be described below with the accompanying drawings. The components roughly included in the radiation imaging apparatus related to the third embodiment of the present invention are similar to the components roughly included in the radiation imaging apparatus 100 related to the first embodiment illustrated in FIG. 1.

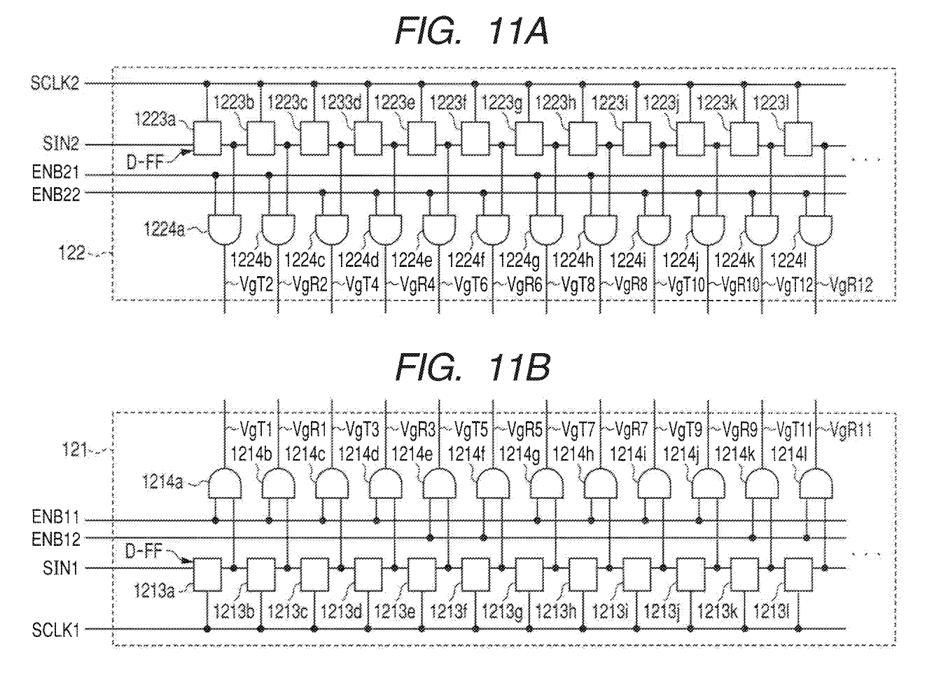

FIGS. 11A and 11B are pattern diagrams exemplifying a third embodiment of the present invention including the interior of a first drive circuit unit and a second drive circuit unit. FIG. 11A illustrates the interior included in the second drive circuit unit 122. FIG. 11B illustrates the interior included in the first drive circuit unit 121.

FIGS. 11A and 11B are different from FIGS. 6A and 6B in the point that two ENB signals (enable signals) are provided for controlling the output from the AND gates (1214a to 12141 and 1224a to 12241). Those two ENB signal lines are brought into connection as illustrated in FIGS. 11A and 11B and, thereby, enable three-pixel addition drive.

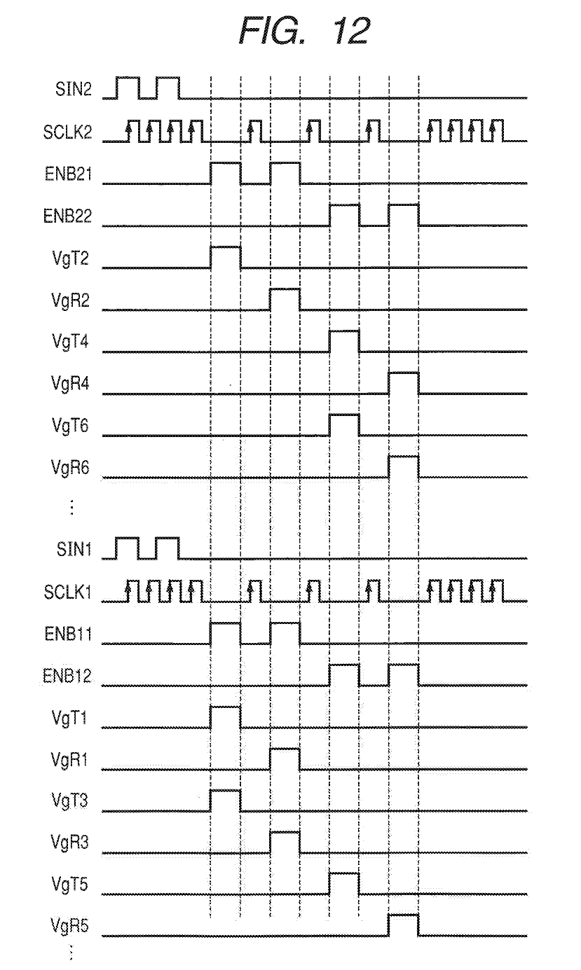

FIG. 12 is a timing chart exemplifying the drive timing of the first drive circuit unit and the second drive circuit unit illustrated in FIGS. 11A and 11B.

Control with one ENB signal (enable signal) as illustrated in FIGS. 6A and 6B cannot drive three-pixel addition. As described in the third embodiment, the control wirings of the AND gates (1214a to 12141 and 1224a to 12241) are devised, enabling desired number of addition drive without being limited to three-pixel addition.

Logic circuit diagrams illustrate the interiors of the drive circuit units in FIGS. 11A, 11B, 6A and 6B. Therefore, the drive wirings of the switching elements are expressed to supply logic outputs from the AND gates. However, actually, for the voltage required for the gates to drive switching element occasionally does not require so-called general logic circuit output level such as 5 V and 3.3 V but higher levels. That is, actually, for example, a level shift circuit not illustrated in the drawing is provided after the AND gate so as to convert the voltage to a desired level for both the state where a current flows and the off state. The respective drive wirings will be provided with those outputs. FIGS. 11A, 11B, 6A and 6B include expression on timing relation. Such as a level shift circuit to adjust the voltage level is omitted.

### Fourth Embodiment

A fourth embodiment of the present invention will be described below with the accompanying drawings. The components roughly included in the radiation imaging apparatus related to the fourth embodiment of the present invention are similar to the components roughly included in the radiation imaging apparatus 100 related to the first embodiment illustrated in FIG. 1.

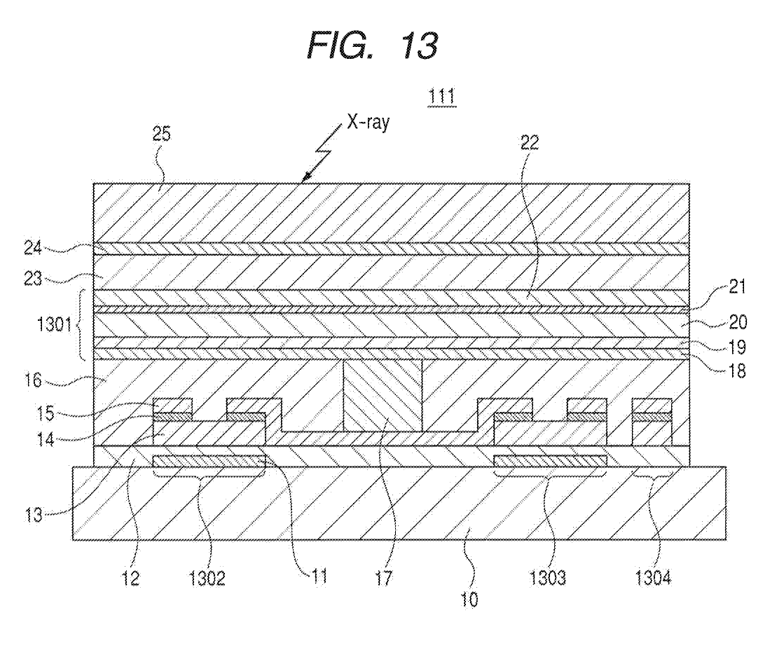

FIG. 13 is a cross-sectional view of a fourth embodiment of the present invention schematically including one pixel included in a converting unit 110.

The pixel 111 of the converting unit 110 is formed to include a first electrically conductive layer 11, a first insulating layer 12, a first semiconductor layer 13, a first impurity semiconductor layer 14 and a second electrically conductive layer 15 being sequentially stacked on a glass substrate 10 being an insulating substrate.

An output switching element 1302, initializing switch element 1303 and wirings included in the pixel 111 are formed in the first electrically conductive layer 11 to the second electrically conductive layer 15 formed on this glass substrate 10. The output switching element 1302 corresponds to the output switching elements TT11 to TT63 illustrated in FIG. 1. The initializing switch element 1303 corresponds to the initializing switch elements TR11 to TR63 illustrated in FIG. 1. In the output switching element 1302 and the initializing switch element 1303, the first electrically conductive layer 11 corresponds to a gate electrode. The second electrically conductive layer 15 corresponds to a source electrode/drain electrode.

Thereafter, an interlayer insulation layer 16 is formed on the second electrically conductive layer 15. A contact hole exposing the second electrically conductive layer 15 is formed in a predetermined region of the relevant interlayer insulation layer 16. A plug 17, for example, embedded in the relevant contact hole is formed.

Conversion elements corresponding to the conversion elements S11 to S63 in FIG. 1 are formed on this interlayer insulation layer 16 and the plug 17 and will be described in detail below.

At first, a third electrically conductive layer 18, a second insulating layer 19, a second semiconductor layer 20, a second impurity semiconductor layer 21 and a fourth electrically conductive layer 22 are sequentially stacked and formed on the interlayer insulation layer 16 and the plug 17. An MIS sensor 1301 corresponding to a photoelectric conversion element is formed in the third electrically conductive layer 18 to the fourth electrically conductive layer 22 formed on this interlayer insulation layer 16 and the plug 17. At this occasion, the third electrically conductive layer 18 corresponds to the lower electrode layer of the MIS sensor 1301. In addition, the fourth electrically conductive layer 22 corresponds to the upper electrode layer of the MIS sensor 1301 and is formed, for example, as a transparent electrode layer. The second impurity semiconductor layer 21 is formed, for example, by an n-type impurity semiconductor layer.

Thereafter, a protective layer 23, an adhesive layer 24 and a phosphor layer (scintillator layer) 25 are sequentially stacked and formed on the fourth electrically conductive layer 22. As described above, the conversion element illustrated in FIG. 1 is formed to include the MIS sensor 1301, the protective layer 23, the adhesive layer 24 and the phosphor layer 25.

As illustrated in FIG. 13, the pixel 111 included in the converting unit 110 is formed in stacked structure provided with conversion elements above the output switching element 1302 and the initializing switch element 1303 with the glass substrate 10 being an insulation substrate as a reference.

That is, the pixel 111 in the present embodiment is formed on not the same layer as the layer for the respective switching elements and conversion elements but on another layer. Thus, forming the respective switching elements and conversion elements in stacked structure is desirable in securing the aperture ratio, that is, the area of the imaging region of the converting unit 110.

In an example illustrated in FIG. 13, the case where the X-ray imaging apparatus is assumed is exemplified. Therefore, the phosphor layer 25 is formed through the protective layer 23 and the adhesive layer 24 above the MIS sensor 1301. In general, the MIS sensor 1301 is formed of any one of thin film semiconductor materials among amorphous silicon, polycrystalline silicon and organic semiconductor as the main material. In that case, the MIS sensor 1301 is little sensitive to X-ray. Therefore, the phosphor layer 25 being wavelength converting element for converting X-ray into visible light is formed above the MIS sensor 1301. A material of a gadolinium system and a material such as CsI (cesium iodide) are used as the phosphor layer 25. Here, in the description so far, the case of assuming a radiation imaging apparatus is exemplified. Therefore, a conversion element provided with a wavelength converting element on the photoelectric conversion element is described. However, it goes without saying that the imaging apparatus functions to pick up an image with incident light if the photoelectric conversion element is used as a conversion element excluding the wavelength converting element.

In the case illustrated in FIG. 13, the X-ray having transmitted an object is converted into visible light by the phosphor layer 25 and reaches the MIS sensor 1301. The MIS sensor 1301 applies photoelectric conversion on the visible light from the phosphor layer 25 with the second semiconductor layer 20 to generate an electric signal (charge). The electric signals (charges) generated by the MIS sensor 1301 are output to the read out circuit unit 130 sequentially by the output switching element 1302 and are read out.

For the present embodiment, the conversion element includes MIS sensor 1301 and the phosphor layer 25. However, the present invention will not be limited thereto. For example, a direct converting conversion element is applicable as the conversion element to convert the incident X-ray directly into electric signal (charge) without providing the phosphor layer 25. In such a case, the direct converting conversion element is preferably made such as of amorphous selenium, gallium arsenide, gallium phosphide, lead iodide, mercuric iodide, CdTe, CdZnTe as the main material.

The photoelectric conversion element will not be limited to the MIS sensor 1301 but pn-type and PIN-type photodiode will work.

### Fifth Embodiment

A fifth embodiment of the present invention will be described below with the accompanying drawing. FIG. 14 is a pattern diagram of a fifth embodiment of the present invention schematically including a radiation imaging system. Here, an X-ray imaging system applied to X-ray as radiation will be described.

In FIG. 14, the converting unit 110, the first drive circuit unit 121 and the second drive circuit unit 122, the sensor bias power supply 140 and the initializing power supply 150 are provided inside an image sensor 6040 in the radiation imaging apparatus 100 illustrated in FIG. 1. For example, the read out circuit unit 130 and the control unit 160 in the radiation imaging apparatus 100 illustrated in FIG. 1 are provided in an image processor 6070 in FIG. 14. For example, the mode selection unit 170 is provided in an operation input apparatus 6071.

For example, when a user instructs X-ray image imaging through the operation input apparatus 6071, the image processor 6070 (control unit 160) controls the pulse-like X-ray 6051 radiation from the X-ray generating unit 6050 to impinge on an object 6060. Thereby, the X-ray having transmitted through the object 6060 reaches the converting unit 110 inside the image sensor 6040. An electric signal (charge) corresponding to the incident X-ray is accumulated in the respective conversion elements. Thereafter, the electric signals (charges) accumulated in the respective conversion elements are read out by the read out circuit unit 130 inside the image processor 6070. Thereafter, the image processor 6070 carries out image process corresponding with an object to generate an X-ray image, which is displayed, for example, on a display 6080 of a control room and is observed.

The X-ray image generated through the image process by the image processor 6070 can be output to a remote place with a communication line 6090. For example, an X-ray image is displayed on a display 6081 in a doctor room through the communication line 6090 to enable diagnosis by a doctor in a remote place. This X-ray image can be recorded as a film 6110 with a film processor 6100.

The radiation imaging apparatus 100 of the above described respective embodiments can be operated by arbitrarily setting and changing resolution and speed in vertical scanning and, therefore, is appropriate for the X-ray imaging system illustrated in FIG. 14.

The respective steps in FIG. 2 specifying the process procedure by the control unit 160 of the radiation imaging apparatus 100 related to the above described respective embodiments can be realized by operating the programs stored in the RAM and the ROM of a computer. This program and the storage medium that can be read out by a computer having stored the relevant program are included in the present invention.

Specifically, the above described program is stored in the storage media such as CD-ROM and provided to a computer through various types of transmission medium. The storage medium for storing the above described program such as a flexible disk, a hard disk, magnetic tape, magnetic optical disk and a nonvolatile memory card can be used beside the CD-ROM. On the other hand, communication medium in a computer network (such as LAN, WAN such as of the Internet, wireless communication network) system for transmitting and supplying program information as carrier wave can be used as transmission medium for the above described program. The communication medium at such an occasion includes a wired line such as made of optical fiber and a wireless line.

The present invention will not be limited to such a mode of realizing the function of the radiation imaging apparatus 100 related to the respective embodiments by a computer executing a supplied program. Also in the case of realizing the function of the radiation imaging apparatus 100 related to the respective embodiments by the program in cooperation with one of an OS (operating system) and another application software being in operation in a computer, such a program is included in the present invention. In the case where one of all and a part of processes of the supplied program are carried out by function expansion board and function expansion unit of a computer to realize the function of the radiation imaging apparatus 100 related to the respective embodiments, such a program is included in the present invention.

Any of the above described embodiments of the present invention just exemplifies specifically for carrying out the present invention. The technical range of the present invention should not be interpreted in a limited manner thereby. That is, the present invention can be carried out in various forms without departing one of its technical philosophy and its main property.

### INDUSTRIAL APPLICABILITY

The present invention relates to an imaging apparatus and a radiation imaging system preferably used for medical diagnosis and industrial nondestructive inspection.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-233313, filed Sep. 7, 2007, which is hereby incorporated by reference herein its entirety.

1. An imaging apparatus comprising:
a conversion unit including a plurality of pixels arranged in a matrix on an insulating substrate, wherein the pixel comprises a conversion element having at least two electrodes and converting radiation or light into an electric signal, an output switching element having two main electrodes one of which is connected to one of the two electrodes of the conversion element for outputting the electric signal, and an initializing switching element having two main electrodes one of which is connected to the one of the two electrodes of the conversion element for initializing the conversion element;
a first drive wiring connected electrically to control electrodes of the output switching elements of the pixels in a predetermined row;
a second drive wiring connected electrically to control electrodes of the initializing switching elements of the pixels in a predetermined row;
a third drive wiring connected electrically to control electrodes of the output switching elements of the pixels in another row different from the predetermined row;
a fourth drive wiring connected electrically to control electrodes of the initializing switching elements of the pixels in the other row;
a first drive circuit unit arranged along a first side of the insulating substrate, and connected electrically to the first and second drive wirings; and
a second drive circuit unit arranged along a second side of the insulating substrate arranged in opposition to the first side sandwiching the conversion unit between the first and second sides, and connected electrically to the third and fourth drive wirings.

2. The imaging apparatus according to claim 1, further comprising a control unit for controlling independently the first and second drive circuits.

3. The imaging apparatus according to claim 2, wherein the control unit controls the first and second drive circuits so as to supply a drive signal in different timings to the first and second drive wirings, and to supply a drive signal in different timings to the third and fourth drive wirings.

4. The imaging apparatus according to claim 2, wherein the control unit controls the first and second drive circuits so as to supply a drive signal in different timings to the first and third drive wirings, and to supply a drive signal in different timings to the second and fourth drive wirings.

5. The imaging apparatus according to claim 2, wherein the control unit controls the first and second drive circuits so as to supply a drive signal in the same timing to the first and third drive wirings, and to supply a drive signal in the same timing to the second and fourth drive wirings.

6. The imaging apparatus according to claim 2, further comprising a mode selecting unit for selecting one operation mode from a plurality of operation modes, wherein
the control unit controls the first and second drive circuits according to the one mode selected by the mode selecting unit.

7. The imaging apparatus according to claim 6, wherein the control unit controls the first and second drive circuits, so that numbers of driving wirings of each of the first and second drive circuits are different, at least, for each of modes selected by the mode selecting unit.

8. The imaging apparatus according to claim 1, wherein
the conversion element has a MIS sensor,
the initializing switching element performs at least one of a refreshment and a reset of the conversion element, and
the imaging apparatus further comprises a power source for supplying a refreshment voltage for the refreshment or a reset voltage for the reset to the other of the two main electrodes the initializing switch element.

9. The imaging apparatus according to claim 1, wherein
the conversion element is formed, as a main ingredient, from at least one thin film semiconductor material selected from amorphous silicon, a poly-silicon and an organic semiconductor.

10. The imaging apparatus according to claim 1, wherein the pixel has a stacked multilayered structure including the conversion element disposed over the output switching element and the initializing switching element with reference to the insulating substrate.

11. An imaging apparatus comprising:
a conversion unit including a plurality of pixels arranged in a matrix on an insulating substrate, wherein the pixel comprises a conversion element having at least two electrodes and converting radiation or light into an electric signal, an output switching element having two main electrodes one of which is connected to one of the two electrodes of the conversion element for performing an outputting operation to output the electric signal, and an initializing switching element having two main electrodes one of which is connected to the one of the two electrodes of the conversion element for initializing operation to initialize the conversion element;
a first drive circuit unit arranged along a first side of the insulating substrate, wherein the first drive circuit unit supplies a first output drive signal for performing the output operation to a control electrode of the output switch elements of the pixels in a predetermined row, and supplies a first initializing drive signal for performing the initializing operation to a control electrode of the initializing switch elements of the pixels in a predetermined row; and
a second drive circuit unit arranged along a second side of the insulating substrate arranged in opposition to the first side sandwiching the conversion unit between the first and second sides, wherein the second drive circuit unit supplies a second output drive signal for performing the output operation to a control electrode of the output switch elements of the pixels in another row different from the predetermined row, and supplies a second initializing drive signal for performing the initializing operation to a control electrode of the initializing switch elements of the pixels in the other row different from the predetermined row.

12. A radiation imaging system comprising:
an imaging apparatus according to claim 1; and
a radiation generating unit for generating radiation so as to impinge on an object, and then to be incident in the conversion element.
